(19) United States
(12) Patent Application Publication
(10) Pub. No.: US 2024/0343938 A1
(43) Pub. Date: Oct. 17, 2024

(54) HARDMASK COMPOSITION, HARDMASK LAYER, AND METHOD OF FORMING PATTERNS

(71) Applicant: Samsung SDI Co., Ltd., Yongin-si (KR)

(72) Inventor: Sunghwan KIM, Suwon-si (KR)

(21) Appl. No.: 18/584,200

(22) Filed: Feb. 22, 2024

(30) Foreign Application Priority Data
Apr. 17, 2023 (KR) 10-2023-0050152

(51) Int. Cl. C09D 165/00; C08G 61/12; H01L 21/027; H01L 21/3213

(52) U.S. Cl. CPC C09D 165/00; C08G 61/12; H01L 21/0271; H01L 21/32139; C08G 2261/11; C08G 2261/1422; C08G 2261/312; C08G 2261/314; C08G 2261/316

(57) ABSTRACT

A hardmask composition, a hardmask layer including a cured product of the hardmask composition, and a method of forming patterns using the hardmask layer including a cured product of the hardmask composition, the hardmask composition including a compound represented by Chemical Formula 1, below; and a solvent,

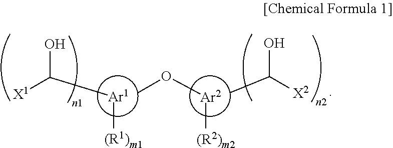

### CROSS-REFERENCE TO RELATED APPLICATION

This application claims priority to and the benefit of Korean Patent Application No. 10-2023-0050152 filed in the Korean Intellectual Property Office on Apr. 17, 2023, the entire contents of which are incorporated herein by reference.

### BACKGROUND

### 1. Field

Embodiments relate to a hardmask composition, a hardmask layer and a method of forming patterns.

### 2. Description of the Related Art

Recently, the semiconductor industry has developed to an ultra-fine technique having a pattern of, e.g., several to several tens nanometer size. Such ultrafine technique essentially needs effective lithographic techniques. Some lithographic technique may include providing a material layer on a semiconductor substrate; coating a photoresist layer thereon; exposing and developing the same to provide a photoresist pattern; and etching a material layer using the photoresist pattern as a mask.

### SUMMARY

The embodiments may be realized by providing a hardmask composition including a compound represented by Chemical Formula 1; and a solvent,

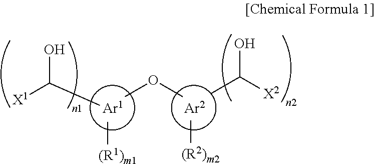

wherein, in Chemical Formula 1,
Ar¹ and Ar² are each independently a C6 to C30 aromatic hydrocarbon group,
X¹ and X² are each independently a substituted or unsubstituted C6 to C30 aromatic hydrocarbon group,
R¹ and R² are each independently deuterium, a hydroxy group, a halogen atom, a substituted or unsubstituted C1 to C20 alkoxy group, a substituted or unsubstituted C1 to C20 alkyl group, a substituted or unsubstituted C6 to C30 aryl group, or a combination thereof,
n1 and n2 are each independently an integer of 0 to 4,
n1+n2 is an integer of 1 or more, and
m1 and m2 are each independently an integer of 0 to less than or equal to a bond valency of Ar¹ and Ar², respectively.
Ar¹ and Ar² in Chemical Formula 1 may each independently be a C6 to C30 aromatic hydrocarbon of Group 1:

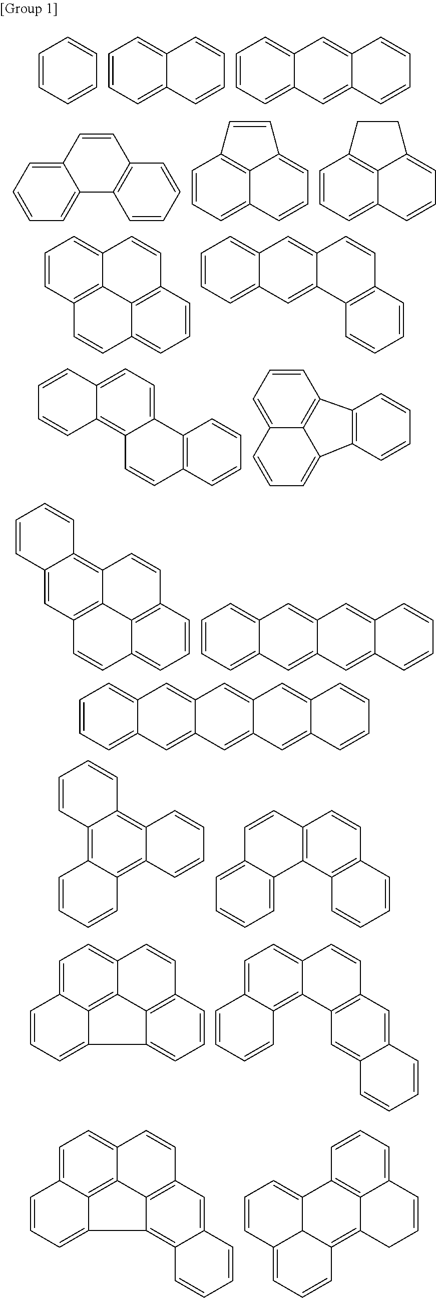

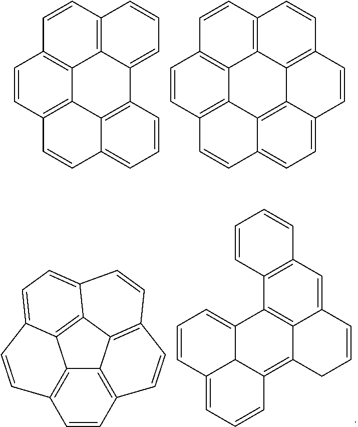

Ar¹ and Ar² in Chemical Formula 1 may each independently be a C6 to C30 aromatic hydrocarbon of Group 1-1:

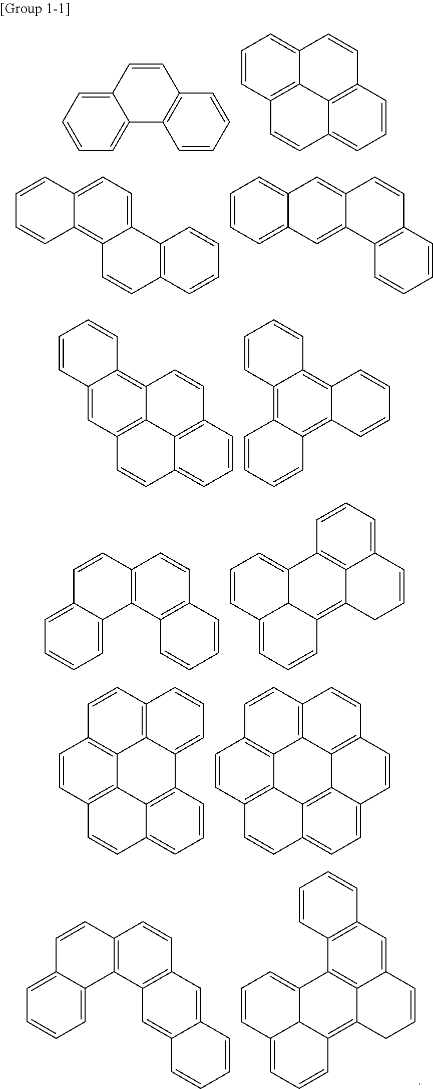

X¹ and X² in Chemical Formula 1 may each independently be a substituted or unsubstituted C6 to C30 aromatic hydrocarbon of a moiety of Group 2:

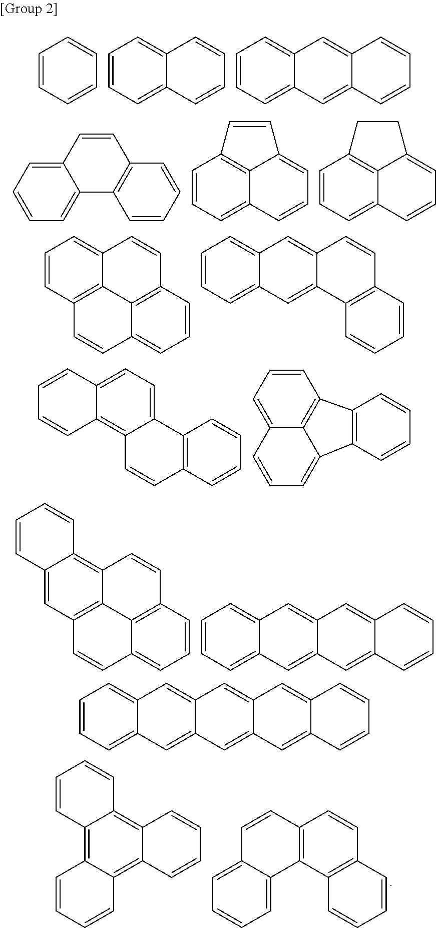

X¹ and X² in Chemical Formula 1 may each independently be a substituted or unsubstituted C6 to C30 aromatic hydrocarbon of a moiety of Group 2-1:

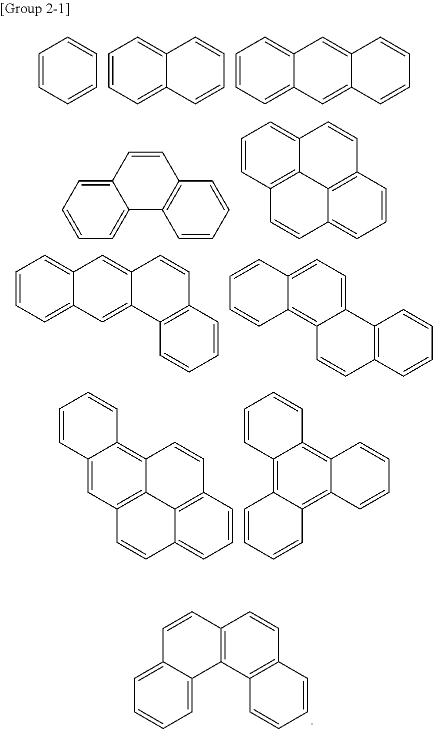

In Chemical Formula 1, Ar¹ and Ar² may each independently be a C6 to C30 aromatic hydrocarbon of Group 1-2, X¹ and X² may each independently be a substituted or unsubstituted phenyl group, substituted or unsubstituted. a substituted naphthyl group, a substituted or unsubstituted phenanthryl group, a substituted or unsubstituted anthryl group, a substituted or unsubstituted pyrenyl group, or a substituted or unsubstituted triphenylenyl group, and n1 and n2 may each independently be 1 or 2:

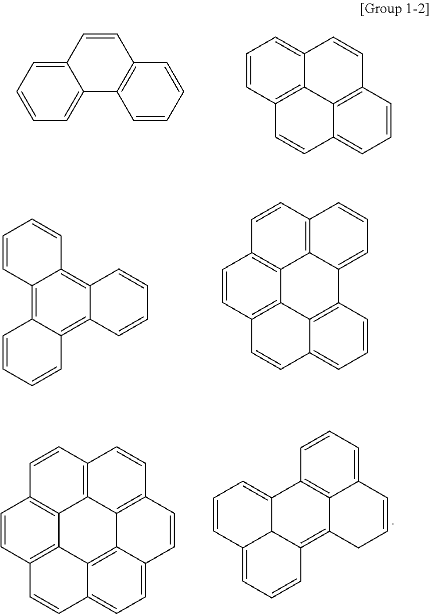

The compound represented by Chemical Formula 1 may be a compound having an asymmetric structure.

The compound represented by Chemical Formula 1 may be represented by one of Chemical Formulas 1-1 to 1-6:

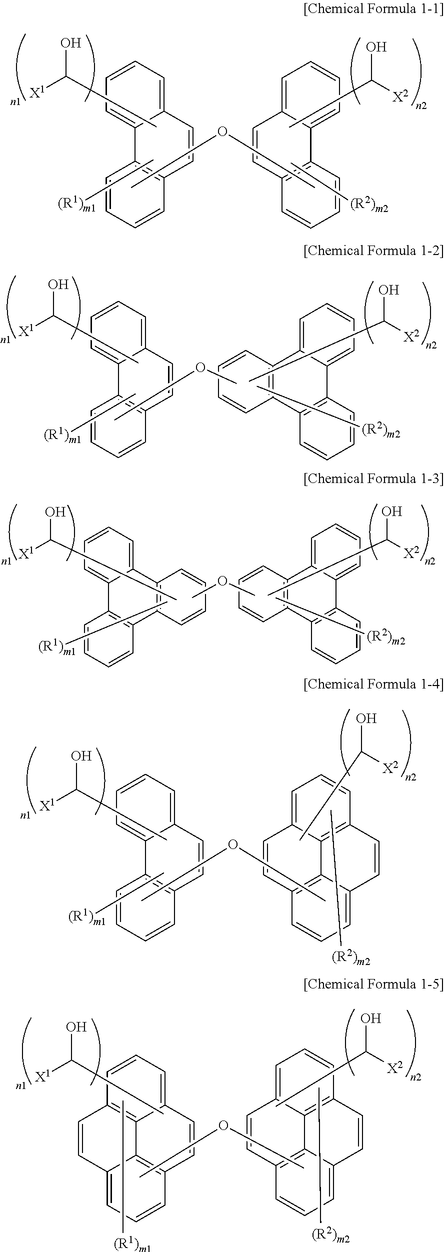

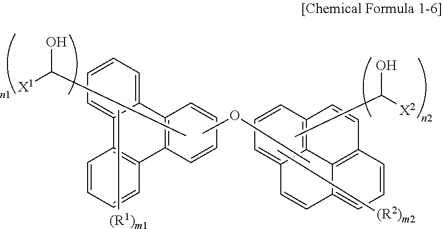

in Chemical Formula 1-1 to Chemical Formula 1-6, X¹ and X² may each independently be a substituted or unsubstituted phenyl group, a substituted or unsubstituted naphthyl group, a substituted or unsubstituted phenanthryl group, a substituted or unsubstituted anthryl group, a substituted or unsubstituted pyrenyl group, or a substituted or unsubstituted triphenylenyl group,
n1 and n2 may be an integer of 0 to 4,
n1+n2 may be an integer of 1 to 4,
R¹ and R² may each independently be deuterium, a hydroxy group, a halogen atom, a substituted or unsubstituted C1 to C20 alkoxy group, a substituted or unsubstituted C1 to C20 alkyl group, a substituted or unsubstituted C6 to C30 aryl group, or a combination thereof, and
m1 and m2 may each independently be an integer of 0 to less than or equal to a bond valency of Ar¹ and Ar², respectively.

In Chemical Formula 1-1 to Chemical Formula 1-6, n1 and n2 may each independently be 1 or 2.

The compound may have a molecular weight of about 500 g/mol to about 10,000 g/mol.

The compound may be included in an amount of about 0.1 wt % to about 30 wt %, based on a total weight of the hardmask composition.

The solvent may include propylene glycol, propylene glycol diacetate, methoxy propanediol, diethylene glycol, diethylene glycol butylether, tri(ethylene glycol)monomethylether, propylene glycol monomethylether, propylene glycol monomethylether acetate, cyclohexanone, ethyllactate, gamma-butyrolactone, N,N-dimethyl formamide, N,N-dimethyl acetamide, methylpyrrolidone, methylpyrrolidinone, acetylacetone, or ethyl 3-ethoxypropionate.

The embodiments may be realized by providing a hardmask layer including a cured product of the hardmask composition.

The embodiments may be realized by providing a method of forming patterns, the method including providing a material layer on a substrate; applying the hardmask composition to the material layer to form a hardmask layer; heat-treating the hardmask composition to form a hardmask layer; forming a photoresist layer on the hardmask layer; exposing and developing the photoresist layer to form a photoresist pattern; selectively removing the hardmask layer using the photoresist pattern to expose a portion of the material layer; and etching an exposed part of the material layer.

Forming the hardmask layer may include heat-treating at about 100° C. to about 1,000° C.

### BRIEF DESCRIPTION OF THE DRAWINGS

Features will become apparent to those of skill in the art by describing in detail exemplary embodiments with reference to the attached drawing in which:

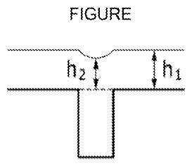

The FIG. 1s a reference diagram illustrating a level difference of a hardmask layer to explain a method of evaluating planarization characteristics.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

As used herein, when a definition is not otherwise provided, ‘substituted’ may refer to replacement of a hydrogen atom of a compound by a substituent selected from a halogen atom (F, Br, Cl, or I), a hydroxy group, an alkoxy group, a nitro group, a cyano group, an amino group, an azido group, an amidino group, a hydrazino group, a hydrazono group, a carbonyl group, a carbamyl group, a thiol group, an ester group, a carboxyl group or a salt thereof, a sulfonic acid group or a salt thereof, a phosphoric acid group or a salt thereof, a vinyl group, a C1 to C20 alkyl group, a C2 to C20 alkenyl group, a C2 to C20 alkynyl group, a C6 to C30 aryl group, a C7 to C30 arylalkyl group, a C9 to C30 allylaryl group, a C1 to C30 alkoxy group, a C1 to C20 heteroalkyl group, a C3 to C20 heteroarylalkyl group, a C3 to C30 cycloalkyl group, a C3 to C15 cycloalkenyl group, a C6 to C15 cycloalkynyl group, a C3 to C30 heterocycloalkyl group, or a combination thereof. As used herein, hydrogen substitution (—H) may include deuterium substitution (-D) or tritium substitution (-T). For example, any hydrogen in any compound described herein may be protium, deuterium, or tritium (e.g., based on natural or artificial substitution). As used herein, the term “or” is not necessarily an exclusive term, e.g., “A or B” would include A, B, or A and B.

In addition, adjacent two substituents of the substituted halogen atom (F, Br, Cl, or I), the hydroxy group, the nitro group, the cyano group, the amino group, the azido group, the amidino group, the hydrazino group, the hydrazono group, the carbonyl group, the carbamyl group, the thiol group, the ester group, the carboxyl group or the salt thereof, the sulfonic acid group or the salt thereof, the phosphoric acid or the salt thereof, the C1 to C30 alkyl group, the C2 to C30 alkenyl group, the C2 to C30 alkynyl group, the C6 to C30 aryl group, the C7 to C30 arylalkyl group, the C1 to C30 alkoxy group, the C1 to C20 heteroalkyl group, the C3 to C20 heteroarylalkyl group, the C3 to C30 cycloalkyl group, the C3 to C15 cycloalkenyl group, the C6 to C15 cycloalkynyl group, the C2 to C30 heterocyclic group may be fused to form a ring.

As used herein, when a definition is not otherwise provided, “aromatic hydrocarbon” refers to a group having one or more hydrocarbon aromatic moieties, including a form in which hydrocarbon aromatic moieties are linked by a single bond, a non-aromatic fused ring form in which hydrocarbon aromatic moieties are fused directly or indirectly, or a combination thereof as well as non-fused aromatic hydrocarbon rings, fused aromatic hydrocarbon rings.

More specifically, the substituted or unsubstituted aromatic hydrocarbon ring may be a substituted or unsubstituted phenyl group, a substituted or unsubstituted naphthyl group, a substituted or unsubstituted anthracenyl group, a substituted or unsubstituted phenanthryl group, a substituted or unsubstituted naphthacenyl group, a substituted or unsubstituted pyrenyl group, a substituted or unsubstituted biphenyl group, a substituted or unsubstituted terphenyl group, a substituted or unsubstituted quaterphenyl group, a substituted or unsubstituted chrysenyl group, a substituted or unsubstituted triphenylenyl group, a substituted or unsubstituted perylenyl group, a substituted or unsubstituted indenyl group, a combination thereof, or a combined fused ring of the foregoing groups.

As used herein, the polymer may include both an oligomer and a polymer.

Unless otherwise specified in the present specification, the “molecular weight” is measured by dissolving a powder sample in tetrahydrofuran (THF) and then using 1200 series Gel Permeation Chromatography (GPC) of Agilent Technologies (column is Shodex Company LF-804, standard sample is Shodex company polystyrene).

The hardmask composition according to some embodiments may include a large monomolecule containing an aromatic hydrocarbon ring, thereby increasing the carbon content in the composition. Accordingly, the hardmask layer formed from the composition may secure excellent heat resistance and excellent etch resistance. In addition, by containing a specific functional group, the compound may increase the carbon content in the composition without reducing solubility in the solvent.

Specifically, the hardmask composition according to some embodiments may include a compound represented by Chemical Formula 1, and a solvent.

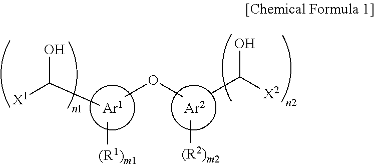

In Chemical Formula 1, Ar¹ and Ar² may each independently be or include, e.g., a C6 to C30 aromatic hydrocarbon group.

X¹ and X² may each independently be or include, e.g., a substituted or unsubstituted C6 to C30 aromatic hydrocarbon group.

R¹ and R² may each independently be or include, e.g., deuterium, a hydroxy group, a halogen atom, a substituted or unsubstituted C1 to C20 alkoxy group, a substituted or unsubstituted C1 to C20 alkyl group, a substituted or unsubstituted C6 to C30 aryl group, or a combination thereof.

n1 and n2 may each independently be an integer of 0 to 4.

n1+n2 may be an integer of 1 or more.

m1 and m2 may each independently be an integer from 0 to less than or equal to a bond valency of each ring. For example, if Ar¹ and Ar² were phenyl groups, m1 and m2 may independently be integers of 1 to 6.

The compound represented by Chemical Formula 1 may be a large monomolecular material that contains two or more aromatic hydrocarbon rings and may be made up of aromatic hydrocarbons linked by a linking group. Accordingly, a hardmask layer formed from a composition according to some embodiments including the compound represented by Chemical Formula 1 with a high carbon content in the compound may have both improved etch resistance and heat resistance. Additionally, since the compound represented by Chemical Formula 1 may be in a monomolecular form, the gap-fill characteristics and void characteristics of a hardmask layer formed from a composition including it may be improved.

The compound represented by Chemical Formula 1 may include an ether group as a linking group, so that the solubility in the solvent may not decrease despite the high carbon content in the compound. In an implementation, the compound represented by Chemical Formula 1 may have increased solubility in solvents by including at least one tertiary carbon substituted with a hydroxy group. In an implementation, the compound represented by Chemical Formula 1 may provide a crosslinking site for polymerization by including a hydroxy group, and therefore, if a composition including the above compound is heated, an aromatic hydrocarbon group represented by Ar¹ or Ar² may be directly linked to the crosslinking site provided by the hydroxy group. Accordingly, the monomolecules represented by Chemical Formula 1 may be polymerized more densely and planarization characteristics, gap-fill characteristics, and void characteristics of the hardmask layer formed therefrom may be further improved.

In an implementation, Ar¹ and Ar² in Chemical Formula 1 may independently be, e.g., a C6 to C30 aromatic hydrocarbon group of Group 1. In an implementation, Ar¹ and Ar² in Chemical Formula 1 may independently be a C6 to C30 aromatic hydrocarbon group of Group 1-1 or Group 1-2.

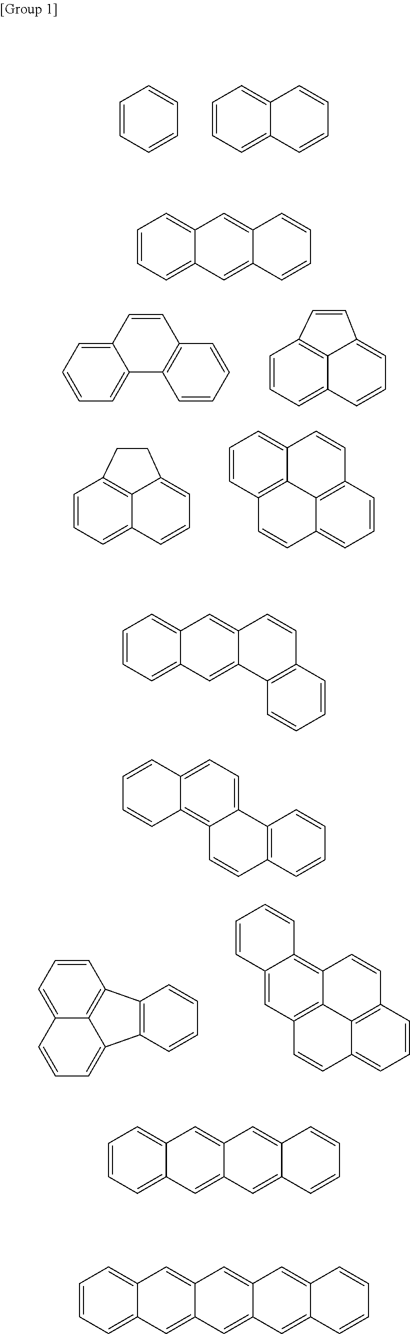

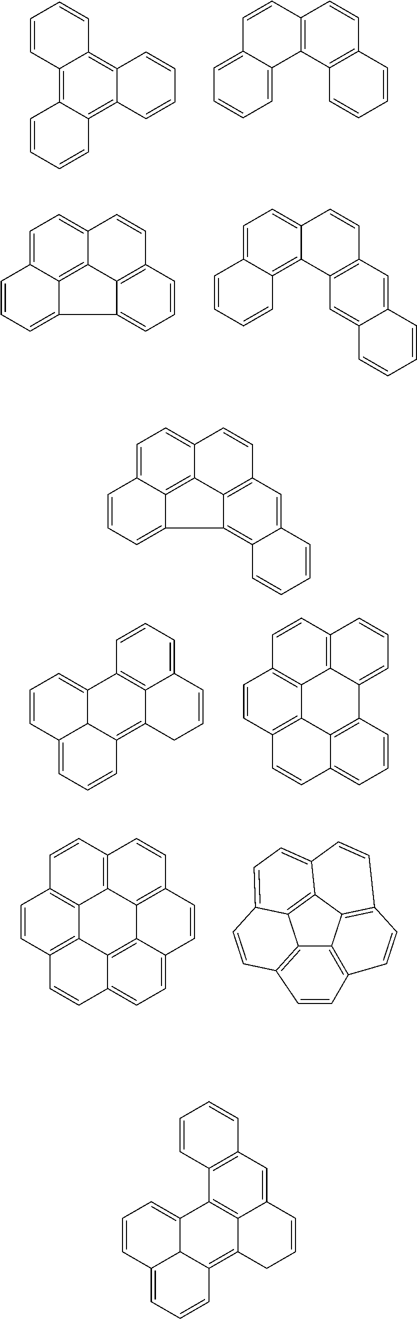

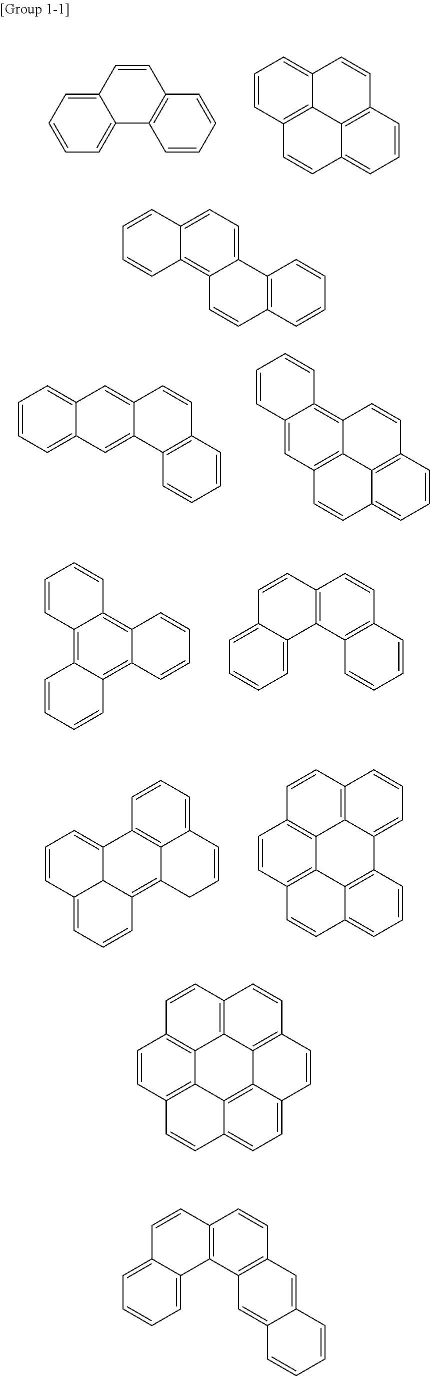

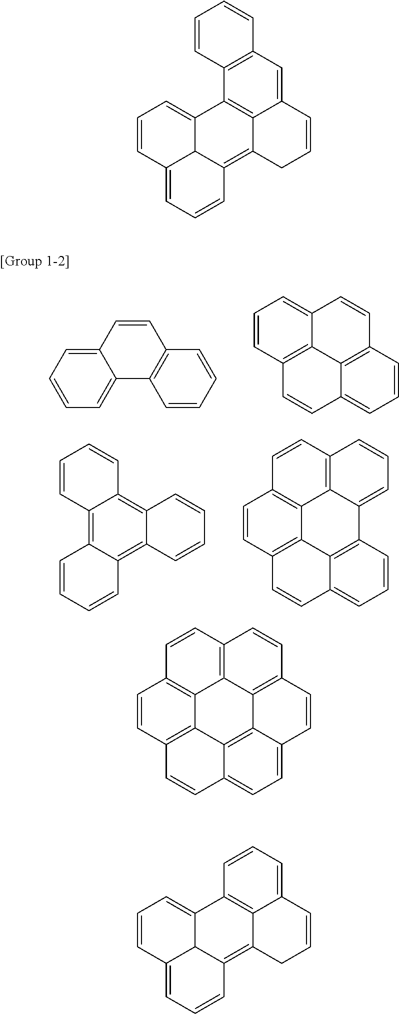

Ar¹ and Ar² of Chemical Formula 1 may be substituted with R¹ or R², or may be unsubstituted. In Chemical Formula 1, R¹ and R² may independently be or include, e.g., deuterium, a hydroxy group, a halogen atom, a substituted or unsubstituted C1 to C10 alkoxy group, a substituted or unsubstituted C1 to C10 alkyl group, a substituted or unsubstituted C6 to C24 aryl group, or a combination thereof. In an implementation, in Chemical Formula 1, R¹ and R² may independently be or include, e.g., deuterium, a hydroxy group, a halogen atom, a substituted or unsubstituted C1 to C5 alkoxy group, a substituted or unsubstituted C1 to C5 alkyl group, a substituted or unsubstituted C6 to C20 aryl group, or a combination thereof. In an implementation, in Chemical Formula 1, R¹ and R² may independently be or include, e.g., a hydroxy group, a halogen atom, a methoxy group, an ethoxy group, a propoxy group, a methyl group, an ethyl group, a propyl group, or a butyl group.

In Chemical Formula 1, X¹ and X² may independently be, e.g., a substituted or unsubstituted C6 to C30 aromatic hydrocarbon group of a moiety of Group 2. In an implementation, in Chemical Formula 1, X¹ and X² may be, e.g., a substituted or unsubstituted C6 to C30 aromatic hydrocarbon group of a moiety of Group 2-1. In an implementation, in Chemical Formula 1, X¹ and X² may be, e.g., a substituted or unsubstituted phenyl group, a substituted or unsubstituted naphthyl group, a substituted or unsubstituted phenanthryl group, a substituted or unsubstituted anthryl group, a substituted or unsubstituted pyrenyl group, or a substituted or unsubstituted triphenylenyl group.

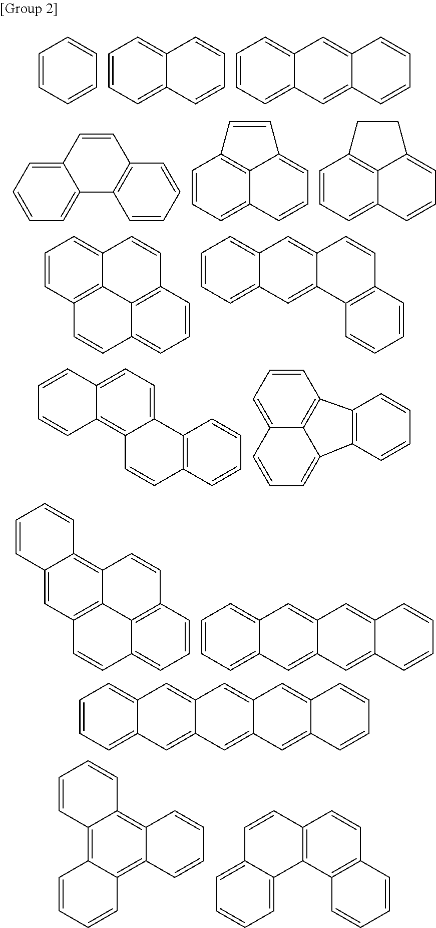

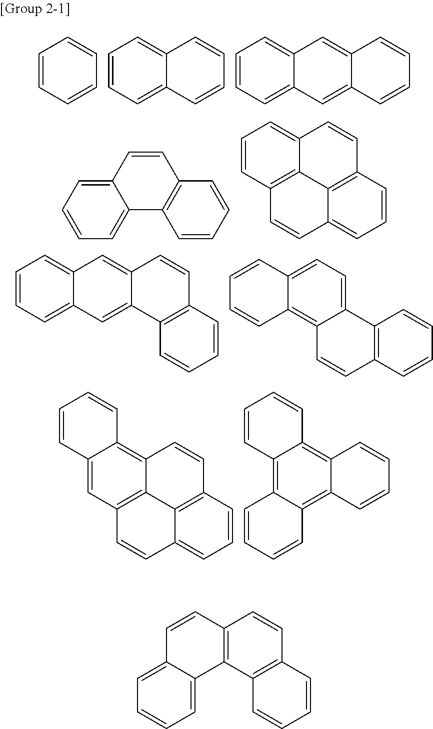

In Chemical Formula 1, n1 and n2 may each independently be an integer of 0 to 4, e.g., an integer of 0 to 3, an integer of 1 to 3, or an integer of 1 or 2. In addition, n1+n2 may be an integer of 1 or more, e.g., an integer of 1 to 6, for example, an integer of 1 to 4, or an integer of 2 or 3.

In Chemical Formula 1, Ar¹ and Ar² may be the same or different. Additionally, X¹ and X² may be the same or different from each other. In an implementation, if Ar¹ and Ar² are the same, the positions of the carbon linked to oxygen (—O—) may be the same or different, and if X¹ and X² are the same, the positions of the carbon linked to the adjacent carbon may be the same or different. Therefore, the compound represented by Chemical Formula 1 may have an overall symmetric structure or an asymmetric structure. In an implementation, if Chemical Formula 1 has an asymmetric structure, solubility of the compound represented by Chemical Formula 1 in a solvent may be higher.

In an implementation, the compound represented by Chemical Formula 1 may be represented by, e.g., one of Chemical Formula 1-1 to Chemical Formula 1-6.

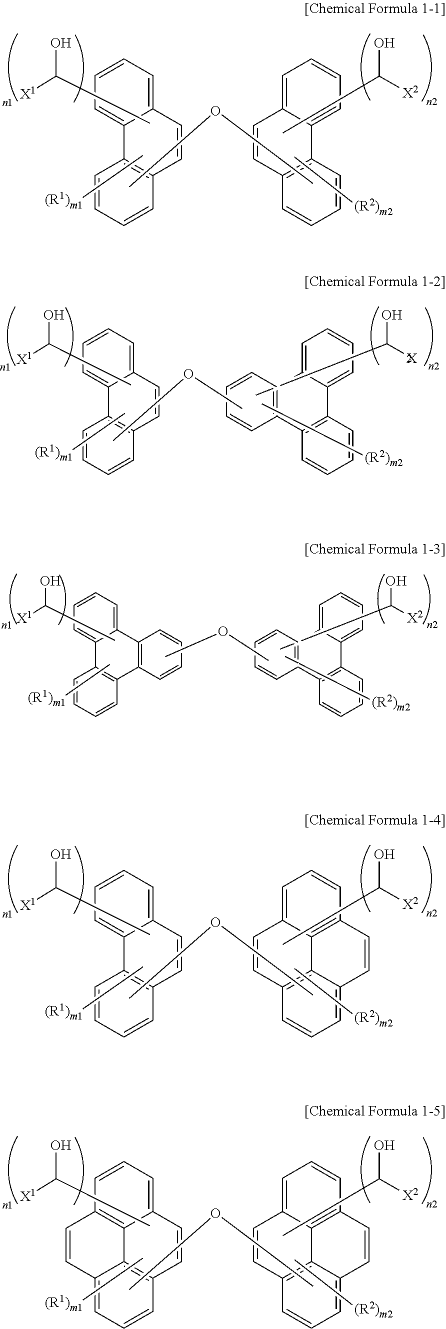

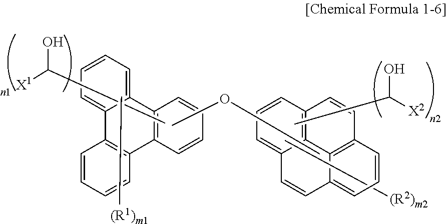

In Chemical Formula 1-1 to Chemical Formula 1-6, X¹, X², R¹, and R² may be the same as defined in Chemical Formula 1, and may be or include, e.g., independently, a substituted or unsubstituted phenyl group, a substituted or unsubstituted naphthyl group, a substituted or unsubstituted phenanthryl group, a substituted or unsubstituted anthryl group, a substituted or unsubstituted pyrenyl group, or a substituted or unsubstituted triphenylenyl group.

In Chemical Formula 1-1 to Chemical Formula 1-6, n1 and n2 may independently be an integer of 0 to 4. n1+n2 may be an integer of 1 to 4. In an implementation, n1 and n2 may be an integer of 0 to 4, e.g., an integer of 0 to 3, an integer of 1 to 3, or an integer of 1 or 2. In an implementation, n1+n2 may be an integer of 1 to 4, e.g., 2 or 3.

In Chemical Formula 1-1 to Chemical Formula 1-6, m1 and m2 may each independently be an integer of 0 to less than or equal to a bond valency of each ring. In an implementation, m1 and m2 may each independently be an integer of 0 to 6, e.g., an integer of 0 to 4, an integer of 0 to 2, or an integer of 0 or 1.

The compound may have a molecular weight of, e.g., about 500 g/mol to about 10,000 g/mol. In an implementation, the compound may have a molecular weight of, e.g., about 500 g/mol to about 9,500 g/mol, about 500 g/mol to about 9,000 g/mol, about 600 g/mol to about 8,500 g/mol, about 600 g/mol to about 8,000 g/mol, about 700 g/mol to about 7,500 g/mol, or about 700 g/mol to about 7,000 g/mol. By having a molecular weight within the above ranges, the carbon content and solubility in the solvent of the hardmask composition including the above compound may be adjusted and optimized.

The compound may be included in an amount of, e.g., about 0.1 wt % to about 30 wt %, based on a total weight of the hardmask composition. In an implementation, the compound may be included in an amount of, e.g., about 0.2 wt % to about 30 wt %, about 0.5 wt % to about 30 wt %, about 1 wt % to about 30 wt %, about 1 wt % to about 25 wt %, or about 1 wt % to about 20 wt %. By including the compound within the above ranges, a thickness, a surface roughness, and a planarization degree of the hardmask may be easily adjusted.

The hardmask composition according to some embodiments may include a solvent. In an implementation, the solvent may include, e.g., propylene glycol, propylene glycol diacetate, methoxy propanediol, diethylene glycol, diethylene glycol butyl ether, tri(ethylene glycol) monomethyl ether, propylene glycol monomethyl ether, propylene glycol monomethyl ether acetate, cyclohexanone, ethyl lactate, gamma-butyrolactone, N,N-dimethylformamide, N,N-dimethylacetamide, methylpyrrolidone, methylpyrrolidinone, acetylacetone, ethyl 3-ethoxypropionate, or the like. In an implementation, the solvent may be a suitable solvent as long as it has sufficient solubility and/or dispersibility for the compound.

In an implementation, the hardmask composition may further include an additive, e.g., such as a surfactant, a crosslinking agent, a thermal acid generator, or a plasticizer.

The surfactant may include, e.g., a fluoroalkyl compound, alkylbenzene sulfonate, alkylpyridinium salt, polyethylene glycol, a quaternary ammonium salt, or the like.

The crosslinking agent may include, e.g., a melamine, a substituted urea, or a polymer crosslinking agent. In an implementation, it may be a crosslinking agent having at least two crosslinking substituents, e.g., methoxymethylated glycoruryl, butoxymethylated glycoruryl, methoxymethylated melamine, butoxymethylated melamine, methoxymethylated benzoguanamine, butoxy methylated benzoguanamine, methoxymethylated urea, butoxymethylated urea, methoxymethylated thiourea, or butoxymethylated thiourea.

In an implementation, as the crosslinking agent, a crosslinking agent having high heat resistance may be used. The crosslinking agent having high heat resistance may include a compound containing a crosslinking substituent having an aromatic ring (e.g., a benzene ring or a naphthalene ring) in the molecule.

The thermal acid generator may include, e.g., an acid compound, such as p-toluenesulfonic acid, trifluoromethanesulfonic acid, pyridinium p-toluenesulfonic acid, salicylic acid, sulfosalicylic acid, citric acid, benzoic acid, hydroxybenzoic acid, naphthalenecarboxylic acid or 2,4,4,6-tetrabromocyclohexadienone, benzointosylate, 2-nitrobenzyltosylate, and other organic sulfonic acid alkyl esters.

In an implementation, a hardmask layer including a cured product of the aforementioned hardmask composition may be provided.

Hereinafter, a method of forming patterns using the aforementioned hardmask composition is described.

A method of forming patterns according to some embodiments may include providing a material layer on a substrate, applying a hardmask composition including the aforementioned compound and solvent to the material layer, heat-treating the hardmask composition to form a hardmask layer, forming a photoresist layer on the hardmask layer, exposing and developing the photoresist layer to form a photoresist pattern, selectively removing the hardmask layer using the photoresist pattern to expose a part of the material layer, and etching the exposed part of the material layer.

The substrate may be, e.g., a silicon wafer, a glass substrate, or a polymer substrate. The material layer may be a material to be finally patterned, e.g., a metal layer such as an aluminum layer or a copper layer, a semiconductor layer such as a silicon layer, or an insulation layer such as a silicon oxide layer or a silicon nitride layer. The material layer may be formed through a method such as a chemical vapor deposition (CVD) process.

The hardmask composition may be the same as described above, and may be applied by spin-on coating in a form of a solution. In an implementation, an application thickness of the hardmask composition may be, e.g., about 50 Å to about 200,000 Å.

The heat-treating of the hardmask composition may be performed, e.g., at about 100° C. to about 1,000° C. for about 10 seconds to about 1 hour. In an implementation, the heat-treating of the hardmask composition may include a plurality of heat-treating processes, e.g., a first heat-treating process, and a second heat-treating process.

In an implementation, the heat-treating of the hardmask composition may include, e.g., one heat-treating process performed at about 100° C. to about 1,000° C. for about 10 seconds to about 1 hour. In an implementation the heat-treating may be performed under an atmosphere of air or nitrogen, or an atmosphere having oxygen concentration of 1 wt % or less.

In an implementation, the heat-treating of the hardmask composition may include, e.g., a first heat-treating process performed at about 100° C. to about 1,000° C., about 100° C. to about 800° C., about 100° C. to about 500° C., or about 150° C. to about 400° C. for about 30 seconds to about 1 hour, about 30 seconds to about 30 minutes, about 30 seconds to about 10 minutes, or about 30 seconds to about 5 minutes.

In an implementation, the heat-treating of the hardmask composition may include, e.g., a second heat-treating process performed at about 100° C. to 1,000° C., about 300° C. to about 1,000° C., about 500° C. to about 1,000° C., or about 500° C. to about 600° C. for about 30 seconds to about 1 hour, about 30 seconds to about 30 minutes, about 30 seconds to about 10 minutes, or about 30 seconds to about 5 minutes, consecutively. In an implementation, the first and second heat-treating process may be performed under an air or nitrogen atmosphere, or may be performed under an atmosphere with an oxygen concentration of 1 wt % or less.

By performing at least one of the steps of heat-treating the hardmask composition at a high temperature, e.g., of 200° C. or higher, high etch resistance capable of withstanding etching gas and chemical liquid exposed in subsequent processes including the etching process may be exhibited.

In an implementation, the forming of the hardmask layer may include a UV/Vis curing process or a near IR curing process.

In an implementation, the forming of the hardmask layer may include a first heat-treating process, a second heat-treating process, a UV/Vis curing process, or a near IR curing process, or may include two or more processes consecutively.

In an implementation, the method may further include forming a silicon-containing thin layer on the hardmask layer. The silicon-containing thin layer may be formed of SiCN, SiOC, SiON, SiOCN, SiC, SiO, SiN, or the like.

In an implementation, the method may further include forming a bottom antireflective coating (BARC) on the silicon-containing thin layer or on the hardmask layer before forming the photoresist layer.

In an implementation, exposure of the photoresist layer may be performed using, e.g., ArF, KrF, or EUV. After exposure, heat-treating may be performed at about 100° C. to about 700° C.

In an implementation, the etching process of the exposed part of the material layer may be performed through a dry etching process using an etching gas and the etching gas may include, e.g., N₂/O₂, CHF₃, CF₄, C1₂, BCl₃, or a mixed gas thereof.

The etched material layer may be formed in a plurality of patterns, and the plurality of patterns may include a metal pattern, a semiconductor pattern, an insulation pattern, or the like, e.g., diverse patterns of a semiconductor integrated circuit device.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### Synthesis of Compounds

### Synthesis Example 1

38.8 g (0.2 mol) of 9-phenanthrol, 7.7 g (0.04 mol) of 4-chlorobenzenesulfonic acid, and 200 mL of 1,2-dichlorobenzene were added in a flask and then, stirred at 180° C. for 12 hours by installing a Dean-Stark trap therein. When a reaction was completed, the resultant was cooled to ambient temperature, the solvent was removed therefrom under a reduced pressure, and Compound 1a represented by Chemical Formula 1a was obtained through column chromatography.

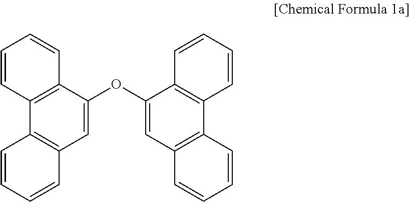 [SMILES: c1ccc2c(c1)cc(Oc1cc3ccccc3c3ccccc13)c1ccccc12]

37.0 g (0.1 mol) of Compound 1a and 28.1 g (0.2 mol) of benzoyl chloride were dissolved in 300 mL of 1,2-dichloroethane, and then, while stirring at ambient temperature, 26.7 g (0.2 mol) of aluminum chloride (AlCl₃) was slowly added thereto in a dropwise fashion over 20 minutes. When a reaction was completed, a product therefrom was added to 500 mL of cold distilled water (DIW), and an organic layer was twice extracted therefrom by using 200 mL of dichloromethane (DCM). After washing the organic layer with 100 mL of a NaHCO₃ aqueous solution and 100 mL of distilled water (DIW), the solvent was removed under a reduced pressure to obtain Compound 1b represented by Chemical Formula 1b.

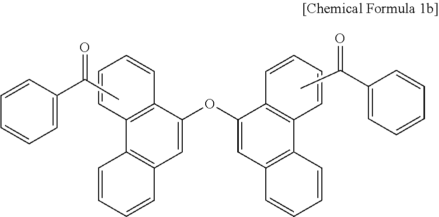

28.9 g (0.05 mol) of Compound 1b was dissolved in 300 mL of methanol/dichloromethane (mixed in a volume ratio of 1:1), and 4.2 g (0.11 mol) of NaBH4 was added thereto and then, stirred at ambient temperature for 8 hours. When a reaction was completed, after additionally adding 200 mL of dichloromethane to the product, an organic layer obtained therefrom was washed with 100 mL of distilled water (DIW), 100 mL of a NaHCO₃ an aqueous solution, and 200 ml of distilled water (DIW) (100 mL×2) in order, and the solvent was removed therefrom under a reduced pressure to obtain Compound 1 represented by Chemical Formula 1-7.

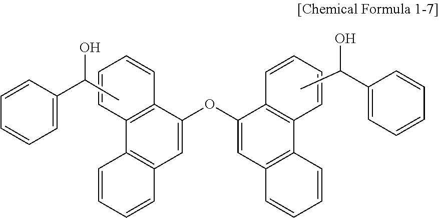

### Synthesis Example 2

Compound 2 represented by Chemical Formula 1-8 was obtained in the same manner as in Synthesis Example 1 except that 2-naphthoylchloride was used in the same number of moles instead of the benzoyl chloride.

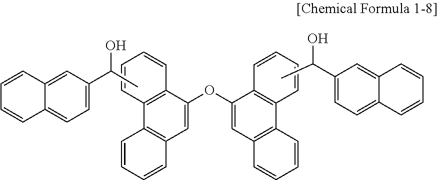

### Synthesis Example 3

Compound 3 represented by Chemical Formula 1-9 was obtained in the same manner as in Synthesis Example 2 except that 19.4 g (0.1 mol) of 9-phenanthrol and 19.4 g (0.1 mol) of 2-phenanthrol were used instead of 38.8 g (0.2 mol) of the 9-phenanthrol.

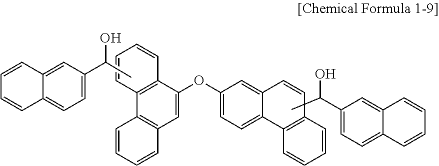

### Synthesis Example 4

Compound 4 represented by Chemical Formula 1-10 was obtained in the same manner as in Synthesis Example 2 except that 19.4 g (0.1 mol) of 9-phenanthrol and 24.4 g (0.1 mol) of 2-hydroxytriphenylene were used instead of 38.8 g (0.2 mol) of the 9-phenanthrol.

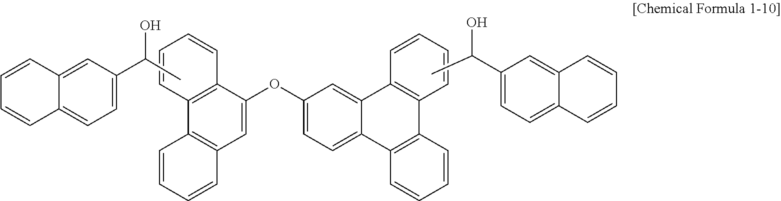

### Synthesis Example 5

Compound 5 represented by Chemical Formula 1-11 was obtained in the same manner as in Synthesis Example 2 except that 4-hydroxypyrene was used in the same number of moles instead of the 9-phenanthrol.

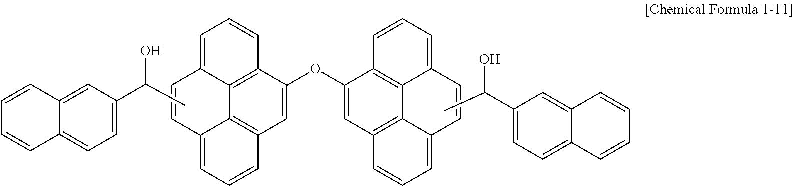

### Synthesis Example 6

Compound 6 represented by Chemical Formula 1-12 was obtained in the same manner as in Synthesis Example 2 except that 21.8 g (0.1 mol) of 1-hydroxypyrene and 21.8 g (0.1 mol) of 4-hydroxypyrene were used instead of 38.8 g (0.2 mol) of the 9-phenanthrol.

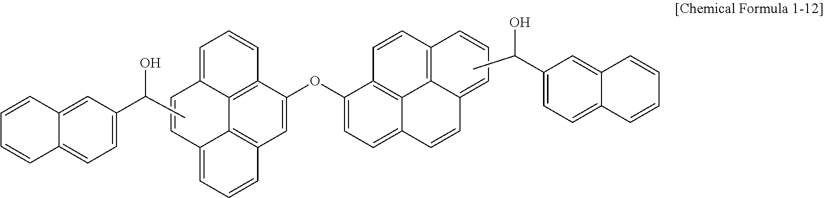

### Synthesis Example 7

Compound 7 represented by Chemical Formula 1-13 was obtained in the same manner as in Synthesis Example 2 except that 21.8 g (0.1 mol) of 1-hydroxypyrene and 21.8 g (0.1 mol) of 4-hydroxypyrene were used instead of 38.8 g (0.2 mol) of the 9-phenanthrol, and the 2-naphthoylchloride was used in an amount of 62.9 g (0.33 mol) instead of 38.13 g (0.2 mol).

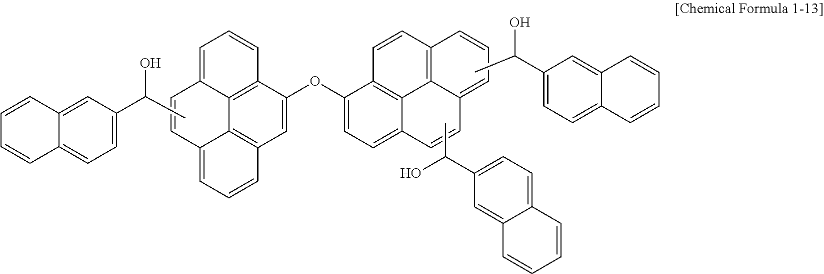

### Comparative Synthesis Example 1

28.83 g (0.2 mol) of 1-naphthol, 41.4 g (0.15 mol) of benzoperylene, and 12.08 g (0.4 mol) of paraformaldehyde (p-formaldehyde) were added in a 3-neck flask, and 0.57 g (0.003 mol) of paratoluene sulfonic acid monohydrate was dissolved in 163 g of propylene glycol monomethyl ether acetate (PGMEA) and then, stirred at 60° C. for 18 hours for polymerization. When a reaction was completed, a product therefrom was added to 40 g of distilled water and 400 g of methanol and then, vigorously stirred and allowed to stand. Subsequently, after removing a supernatant therefrom, precipitates were dissolved in 80 g of PGMEA and then, vigorously stirred by using 320 g of methanol and then, allowed to stand. After twice further repeating the purification, the purified polymer was dissolved in 80 g of propylene glycol monomethyl ether acetate (PGMEA), and methanol and distilled water remaining in the solution were removed under a reduced pressure. Herein, after adding 1 L of tetrahydrofuran (THF) to the concentrated solution, the solution was slowly added in a dropwise fashion to a beaker containing 1 L of hexane to form precipitates and thus obtain Comparative Compound A represented by Chemical Formula A. Comparative Compound A had a weight average molecular weight (Mw) of 4,000 g/mol and polydispersity (PD) of 1.75.

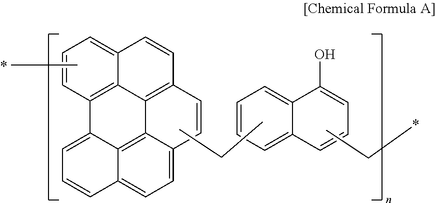

### Comparative Synthesis Example 2

Comparative Compound B represented by Chemical Formula B was obtained in the same manner as in Synthesis Example 2 except that 28 g (0.1 mol) of benzoperylene was used instead of Compound 1a.

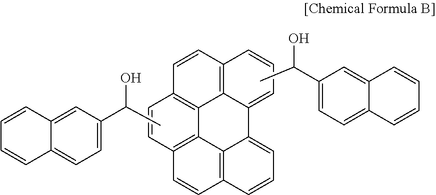

### Preparation of Hardmask Composition

### Example 1

A hardmask composition solution was prepared by dissolving 3.5 g of Compound 1 according to Synthesis Example 1 in 10 g of a solvent of propylene glycol methyl ether acetate and cyclohexanone mixed in a volume ratio of 7:3 and then, filtering the solution with a syringe filter.

### Example 2

A hardmask composition was prepared in the same manner as in Example 1 except that Compound 2 was used instead of Compound 1.

### Example 3

A hardmask composition was prepared in the same manner as in Example 1 except that Compound 3 was used instead of Compound 1.

### Example 4

A hardmask composition was prepared in the same manner as in Example 1 except that Compound 4 was used instead of Compound 1.

### Example 5

A hardmask composition was prepared in the same manner as in Example 1 except that Compound 5 was used instead of Compound 1.

### Example 6

A hardmask composition was prepared in the same manner as in Example 1 except that Compound 6 was used instead of Compound 1.

### Example 7

A hardmask composition was prepared in the same manner as in Example 1 except that Compound 7 was used instead of Compound 1.

### Comparative Example 1

A hardmask composition was prepared in the same manner as in Example 1 except that Comparative Compound A was used instead of Compound 1.

### Comparative Example 2

A hardmask composition was prepared in the same manner as in Example 1 except that Comparative Compound B was used instead of Compound 1.

### Evaluation 1: Evaluation of Etch Resistance

Each of the hardmask compositions of Examples 1 to 7 and Comparative Examples 1 to 2 were coated on a silicon wafer and heat-treated on a hot plate at 400° C. for 2 minutes to form a 4,000 Å-thick hardmask layer. The hardmask layer was dry-etched with CFx mixed gas and N₂/O₂ mixed gas and then, measured with respect to each hardmask thickness before and after the etching by using a film thickness meter made by K-MAC Co., Ltd., and an etch rate was calculated according to Calculation Equation 1. The results are shown in Table 1.

### [Calculation Equation 1]

Etch rate (Å/s)=(initial thin film thickness−thin film thickness after etching)/etching time (s)

TABLE 1

Bulk etch rate (Å/sec)

| | CFx etch | N₂/O₂ etch |
|---|---|---|
| Example 1 | 23.6 | 23.0 |
| Example 2 | 23.3 | 22.8 |
| Example 3 | 22.9 | 23.2 |
| Example 4 | 23.0 | 23.4 |
| Example 5 | 21.7 | 22.9 |
| Example 6 | 22.3 | 21.8 |
| Example 7 | 22.2 | 21.2 |
| Comparative Example 1 | 25.9 | 24.1 |
| Comparative Example 2 | 24.7 | 23.8 |

Referring to Table 1, the hardmask layers formed of the hardmask compositions according to the Examples exhibited a relatively small etch rate and thus excellent etch resistance, compared with the hardmask layers of the hardmask compositions according to the Comparative Examples.

### Evaluation 2: Evaluation of Planarization Characteristics and Gap-fill Characteristics

Each of the hardmask compositions of Examples 1 to 7 and Comparative Examples 1 to 2 were coated on a patterned wafer and then, heat-treated on a hot plate at 400° C. for 2 minutes to form a 2,000 Å-thick hardmask layer. The FIG. 1s a reference view exemplarily showing a step of the hardmask layers in order to explain a method of evaluating planarization characteristics. The planarization characteristics were evaluated by using a thin film thickness meter made by K-MAC Co., Ltd. to measure a thickness at three random points on a non-patterned portion of a substrate and calculate an average h1 thereof and also, measure a thickness of a thin film at three random points on a patterned portion of the substrate and calculate an average h2 thereof and thus to calculate a step (|h₁−h₂|). The smaller step (|h₁−h₂|), the better planarization characteristics. The gap-fill characteristics were evaluated by observing the cross-section of the pattern with a scanning electron microscope (SEM) to check whether voids were generated or not, and the results are shown in Table 2.

TABLE 2

| | Planarization characteristics (\|h₁ − | | |
|---|---|---|---|
| | h₂\|, Å) | | |
| | aspect ratio | aspect ratio | Gap-fill characteristics |
| | (1:2) | (1:10) | (with or without void) |
| Example 1 | 65 | 126 | Voids are not present |
| Example 2 | 80 | 165 | Voids are not present |
| Example 3 | 58 | 132 | Voids are not present |
| Example 4 | 92 | 152 | Voids are not present |
| Example 5 | 82 | 148 | Voids are not present |
| Example 6 | 65 | 118 | Voids are not present |
| Example 7 | 69 | 129 | Voids are not present |
| Comparative | 132 | 265 | Voids are generated |
| Example 1 | | | |
| Comparative | 96 | 321 | Voids are generated |
| Example 2 | | | |

Referring to Table 2, the hardmask layers formed of the hardmask compositions of Comparative Examples 1 and 2 exhibited a relatively large difference of h₁ and h₂ and simultaneously, voids in the pattern. In other words, the hardmask layers formed of the hardmask compositions of Comparative Examples 1 and 2 did not exhibit good planarization and also demonstrated inferior gap-fill characteristics. On the contrary, the hardmask layers formed of the hardmask compositions of Examples 1 to 7 exhibited a relatively small difference of h₁ and h₂ and no voids in the pattern. In other words, the hardmask layers formed of the hardmask compositions of the Examples exhibited excellent planarization characteristics and also, excellent gap-fill characteristics.

By way of summation and review, when small-sizing the pattern to be formed, it may be difficult to provide a fine pattern having an excellent profile by a typical lithographic technique. Accordingly, an auxiliary layer, called a hardmask layer, may be formed between the material layer and the photoresist layer to provide a fine pattern.

This hardmask layer may serve as an interlayer that transfers a fine pattern of the photoresist through selective etching. Therefore, the hardmask layer may have sufficient etch resistance as to withstand the etching process during the pattern transfer. Accordingly, research is being conducted to maximize the carbon content contained in the hardmask composition to improve the etch resistance of the hardmask layer.

Some hardmask layers may be formed in a chemical or physical deposition method and may have low economic efficiency due to a large-scale equipment and a high process cost. The spin-coating technique for forming a hardmask layer has recently been developed. The spin-coating technique may be an easier process to conduct than the conventional method, and a hardmask layer formed therefrom may exhibit much more excellent gap-fill characteristics and planarization characteristics. However, the required etch resistance may be somewhat lowered. Accordingly, a hardmask composition may be required to apply to the spin-coating technique and to secure equivalent etch resistance to that of the hardmask layer formed in the chemical or physical deposit method.

In order to improve the etch resistance of a hardmask layer, research on maximizing a carbon content of the hardmask composition is being made. As a carbon content of a compound included in the hardmask composition is maximized, solubility of the compound in a solvent may tend to decrease. A carbon content of the compound included in the hardmask composition may be maximized to improve the etch resistance of the hardmask layer formed therefrom, while the compound should be well soluble in the solvent.

One or more embodiments may provide a hardmask composition that can be effectively applied to a hardmask layer.

One or more embodiments may provide a hardmask layer including a cured product of the hardmask composition.

One or more embodiments may provide a method of forming patterns using the hardmask composition.

The hardmask layer formed from the hardmask composition according to some embodiments may help secure excellent etch resistance.

The hardmask layer formed from a hardmask composition according to some embodiments may help secure excellent gap-fill characteristics and heat resistance.

Example embodiments have been disclosed herein, and although specific terms are employed, they are used and are to be interpreted in a generic and descriptive sense only and not for purposes of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A hardmask composition, comprising:
a compound represented by Chemical Formula 1; and
a solvent, 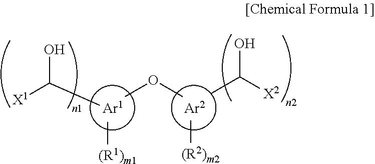
wherein, in Chemical Formula 1,
Ar¹ and Ar² are each independently a C6 to C30 aromatic hydrocarbon group,
X¹ and X² are each independently a substituted or unsubstituted C6 to C30 aromatic hydrocarbon group,
R¹ and R² are each independently deuterium, a hydroxy group, a halogen atom, a substituted or unsubstituted C1 to C20 alkoxy group, a substituted or unsubstituted C1 to C20 alkyl group, a substituted or unsubstituted C6 to C30 aryl group, or a combination thereof,
n1 and n2 are each independently an integer of 0 to 4,
n1+n2 is an integer of 1 or more, and
m1 and m2 are each independently an integer of 0 to less than or equal to a bond valency of Ar¹ and Ar², respectively.

2. The hardmask composition as claimed in claim 1, wherein Ar¹ and Ar² in Chemical Formula 1 are each independently a C6 to C30 aromatic hydrocarbon of Group 1:

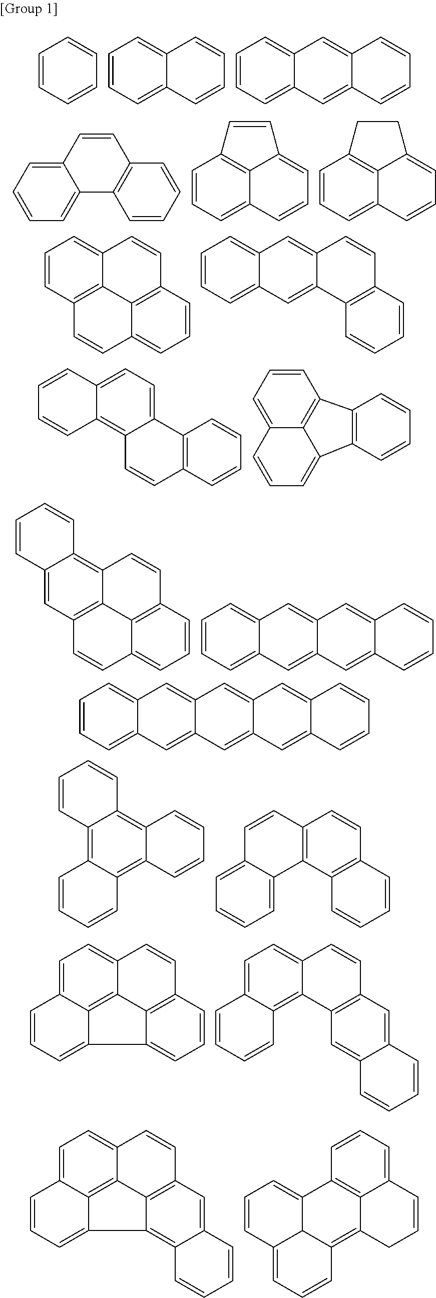

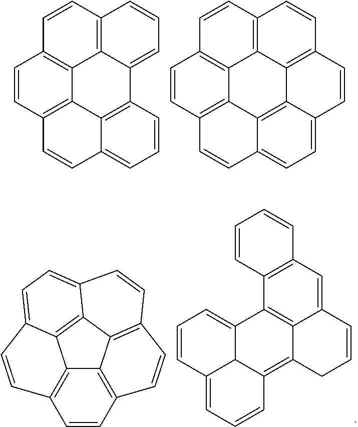

3. The hardmask composition as claimed in claim 1, wherein Ar¹ and Ar² in Chemical Formula 1 are each independently a C6 to C30 aromatic hydrocarbon of Group 1-1:

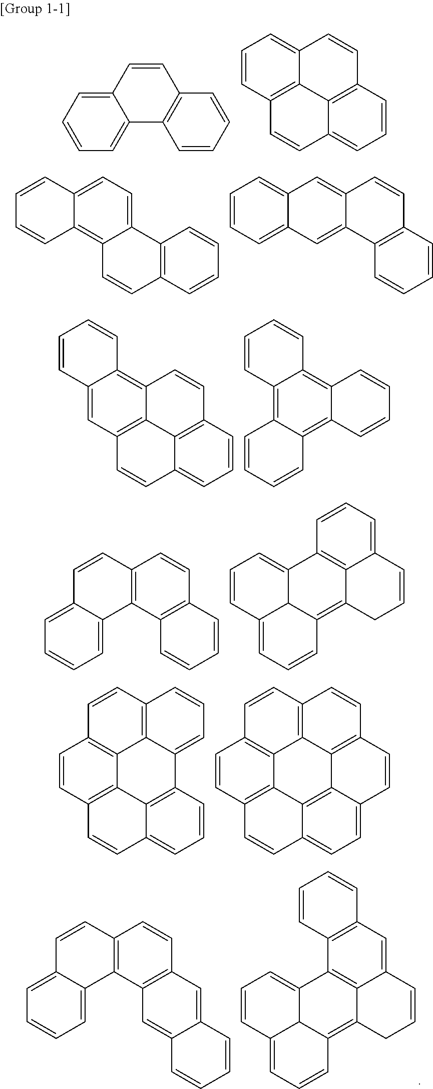

4. The hardmask composition as claimed in claim 1, wherein X¹ and X² in Chemical Formula 1 are each independently a substituted or unsubstituted C6 to C30 aromatic hydrocarbon of a moiety of Group 2:

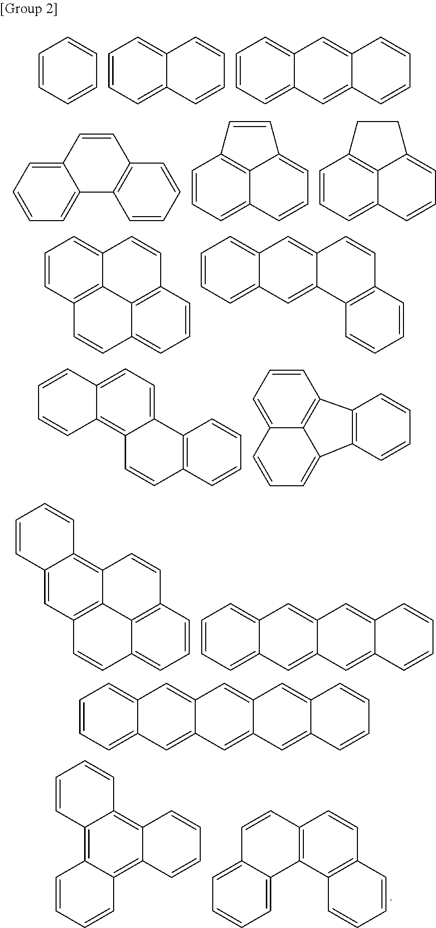

5. The hardmask composition as claimed in claim 1, wherein X¹ and X² in Chemical Formula 1 are each independently a substituted or unsubstituted C6 to C30 aromatic hydrocarbon of a moiety of Group 2-1:

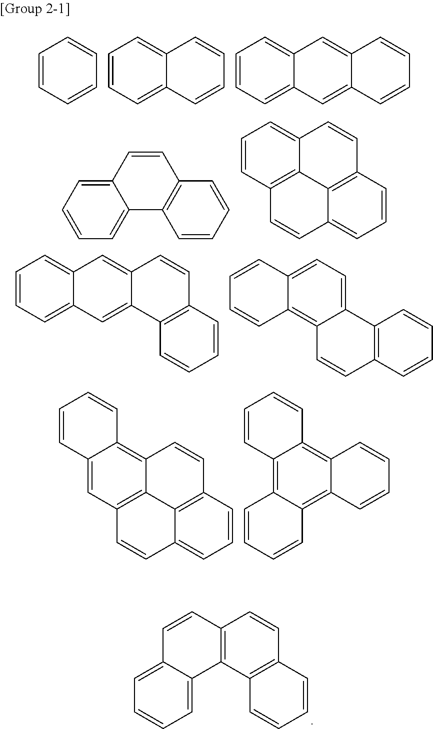

6. The hardmask composition as claimed in claim 1, wherein:
Ar¹ and Ar² in Chemical Formula 1 are each independently a C6 to C30 aromatic hydrocarbon of Group 1-2,
X¹ and X² are each independently a substituted or unsubstituted phenyl group, a substituted or unsubstituted naphthyl group, a substituted or unsubstituted phenanthryl group, a substituted or unsubstituted anthryl group, a substituted or unsubstituted pyrenyl group, or a substituted or unsubstituted triphenylenyl group,
and n1 and n2 are each independently 1 or 2:

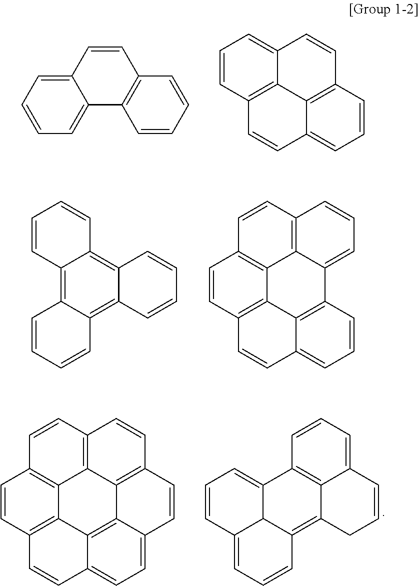

7. The hardmask composition as claimed in claim 1, wherein the compound represented by Chemical Formula 1 has an asymmetric structure.

8. The hardmask composition as claimed in claim 1, wherein the compound represented by Chemical Formula 1 is represented by one of Chemical Formula 1-1 to Chemical Formula 1-6: 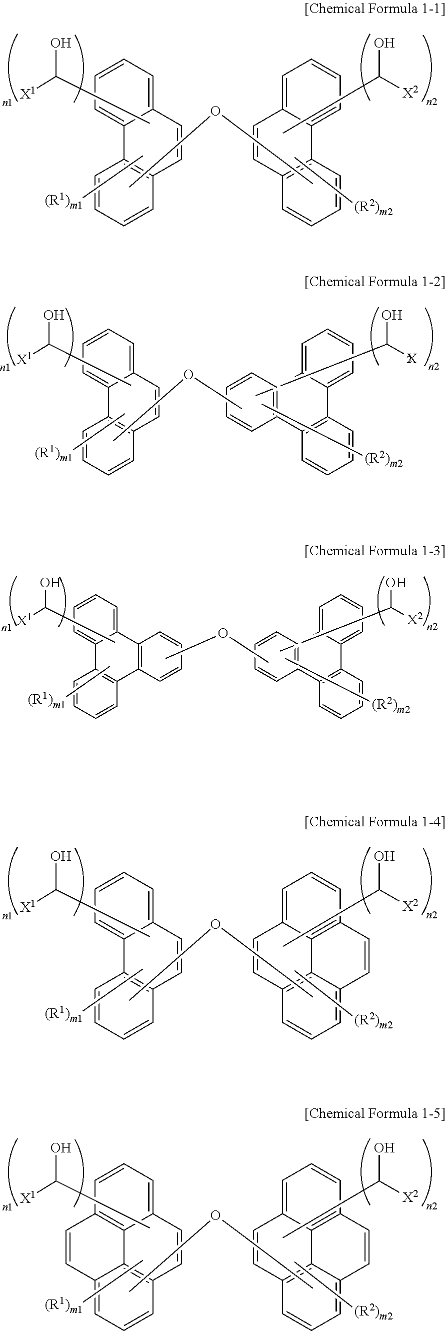 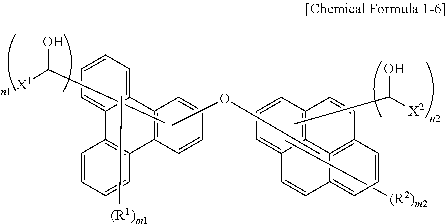
in Chemical Formula 1-1 to Chemical Formula 1-6,
X¹ and X² are each independently a substituted or unsubstituted phenyl group, a substituted or unsubstituted naphthyl group, a substituted or unsubstituted phenanthryl group, a substituted or unsubstituted anthryl group, a substituted or unsubstituted pyrenyl group, or a substituted or unsubstituted triphenylenyl group,
n1 and n2 are an integer of 0 to 4,
n1+n2 is an integer of 1 to 4,
R¹ and R² are each independently deuterium, a hydroxy group, a halogen atom, a substituted or unsubstituted C1 to C20 alkoxy group, a substituted or unsubstituted C1 to C20 alkyl group, a substituted or unsubstituted C6 to C30 aryl group, or a combination thereof, and
m1 and m2 are each independently an integer of 0 to less than or equal to a bond valency of Ar¹ and Ar², respectively.

9. The hardmask composition as claimed in claim 8, wherein in Chemical Formula 1-1 to Chemical Formula 1-6, n1 and n2 are each independently 1 or 2.

10. The hardmask composition as claimed in claim 1, wherein the compound has a molecular weight of about 500 g/mol to about 10,000 g/mol.

11. The hardmask composition as claimed in claim 1, wherein the compound is included in an amount of about 0.1 wt % to about 30 wt %, based on a total weight of the hardmask composition.

12. The hardmask composition as claimed in claim 1, wherein the solvent includes propylene glycol, propylene glycol diacetate, methoxy propanediol, diethylene glycol, diethylene glycol butylether, tri(ethylene glycol)monomethylether, propylene glycol monomethylether, propylene glycol monomethylether acetate, cyclohexanone, ethyllactate, gamma-butyrolactone, N,N-dimethyl formamide, N,N-dimethyl acetamide, methylpyrrolidone, methylpyrrolidinone, acetylacetone, or ethyl 3-ethoxypropionate.

13. A hardmask layer comprising a cured product of the hardmask composition as claimed in claim 1.

14. A method of forming patterns, the method comprising:
providing a material layer on a substrate;
applying the hardmask composition as claimed in claim 1 to the material layer;
heat-treating the hardmask composition to form a hardmask layer;
forming a photoresist layer on the hardmask layer;
exposing and developing the photoresist layer to form a photoresist pattern;
selectively removing the hardmask layer using the photoresist pattern to expose a portion of the material layer; and
etching an exposed part of the material layer.

15. The method as claimed in claim 14, wherein forming the hardmask layer includes heat-treating at about 100° C. to about 1,000° C.
